(19) United States
(12) Patent Application Publication
(10) Pub. No.: US 2024/0222092 A1
(43) Pub. Date: Jul. 4, 2024

(54) PLASMA PROCESSING APPARATUS AND ELECTROSTATIC CHUCK INCLUDING A DIELECTRIC STRUCTURE AND AN ELECTROSTATIC CLAIM ELECTRODE INSIDE THE DIELECTRIC STRUCTURE

(71) Applicant: Tokyo Electron Limited, Tokyo (JP)

(72) Inventors: Takahiko SATO, Miyagi (JP); Tetsuo YOSHIDA, Miyagi (JP)

(73) Assignee: Tokyo Electron Limited, Tokyo (JP)

(21) Appl. No.: 18/606,853

(22) Filed: Mar. 15, 2024

Related U.S. Application Data
(63) Continuation of application No. PCT/JP2022/038802, filed on Oct. 18, 2022.
(60) Provisional application No. 63/272,717, filed on Oct. 28, 2021.

(30) Foreign Application Priority Data
May 17, 2022 (JP) 2022-080683

(51) Int. Cl. H01J 37/32

(52) U.S. Cl. CPC H01J 37/32715; H01J 2237/2007

(57) ABSTRACT

A plasma processing apparatus includes a plasma processing chamber, a base in the plasma processing chamber, and an electrostatic chuck on the base. The electrostatic chuck includes a dielectric structure having a substrate support surface and a ring support surface, an electrostatic clamp electrode inside the dielectric structure, a bias electrode inside the dielectric structure and below the electrostatic clamp electrode, and at least one conductive structure at least partially located inside the dielectric structure. The dielectric structure has a through-hole extending through the dielectric structure from the substrate support surface or the ring support surface to a lower surface of the dielectric structure. The at least one conductive structure surrounds the through-hole and extends upward from a same level as the bias electrode in a height direction or from a higher level than the bias electrode.

### CROSS-REFERENCE TO RELATED APPLICATIONS

This application is a bypass continuation application of international application No. PCT/JP2022/038802 having an international filing date of Oct. 18, 2022 and designating the United States, the international application being based upon and claiming the benefit of priority from Japanese Patent Application No. 2022-080683, filed on May 17, 2022, and claiming the benefit of priority of U.S. Provisional Application No. 63/272,717, filed on Oct. 28, 2021, the entire contents of each are incorporated herein by reference.

### FIELD

The disclosure relates to a plasma processing apparatus and an electrostatic chuck (ESC).

### BACKGROUND

Patent Literature 1 describes a plasma processing apparatus including a plasma processing chamber and a substrate support in the plasma processing chamber. The substrate support includes a base and an ESC. The ESC has a through-hole for supplying a heat transfer gas into a space between the back surface of a substrate and the surface of the ESC, and a through-hole for receiving a lifter pin to raise and lower the substrate.

### CITATION LIST

### Patent Literature

Patent Literature 1: Japanese Unexamined Patent Application Publication No. 2021-28958

### SUMMARY

One or more aspects of the disclosure are directed to a technique for preventing or reducing occurrence of abnormal discharge in through-holes in an ESC.

A plasma processing apparatus according to one aspect of the disclosure includes a plasma processing chamber, a base in the plasma processing chamber, and an electrostatic chuck on the base. The electrostatic chuck includes a dielectric structure having a substrate support surface and a ring support surface, an electrostatic clamp electrode inside the dielectric structure, a bias electrode inside the dielectric structure and below the electrostatic clamp electrode, and at least one conductive structure at least partially located inside the dielectric structure. The dielectric structure has a through-hole extending through the dielectric structure from the substrate support surface or the ring support surface to a lower surface of the dielectric structure. The at least one conductive structure surrounds the through-hole and extends upward from a same level as the bias electrode in a height direction or from a higher level than the bias electrode.

The structure according to the above aspect of the disclosure prevents or reduces occurrence of abnormal discharge in the through-hole in the electrostatic chuck.

### BRIEF DESCRIPTION OF THE DRAWINGS

FIG. 1 is a diagram of a plasma processing system with an example structure.

FIG. 2 is a diagram of a capacitively coupled plasma processing apparatus with an example structure.

FIG. 3 is a schematic sectional view of a substrate support with an example structure.

FIG. 4 is a schematic top view of the substrate support with an example structure.

FIG. 5A is a sectional view of a conductive structure in a first embodiment.

FIG. 5B is a top view of the conductive structure in the first embodiment.

FIG. 6A is a top view of conductive structures with example shapes.

FIG. 6B is a top view of conductive structures with example shapes.

FIG. 6C is a top view of conductive structures with example shapes.

FIG. 6D is a top view of conductive structures with example shapes.

FIG. 6E is a top view of conductive structure with an example shape.

FIG. 7A is a sectional view of conductive structures with example shapes.

FIG. 7B is a sectional view of conductive structures with example shapes.

FIG. 7C is a sectional view of conductive structures with example shapes.

FIG. 8 is a sectional view of a conductive structure in a second embodiment.

FIG. 9 is a sectional view of a conductive structure in a third embodiment.

FIG. 10 is a sectional view of a conductive structure in a fourth embodiment.

FIG. 11 is a sectional view of a conductive structure in a fifth embodiment.

FIG. 12 is a sectional view of a conductive structure in a sixth embodiment.

FIG. 13A is a sectional view of a conductive structure in a seventh embodiment.

FIG. 13B is a sectional view of the conductive structure in the seventh embodiment.

### DETAILED DESCRIPTION

An electrostatic chuck (ESC) and a plasma processing apparatus according to the present embodiment will now be described with reference to the drawings. Like reference numerals denote components having substantially the same functions herein and in the drawings. Such components will not be described repeatedly.

### Plasma Processing System

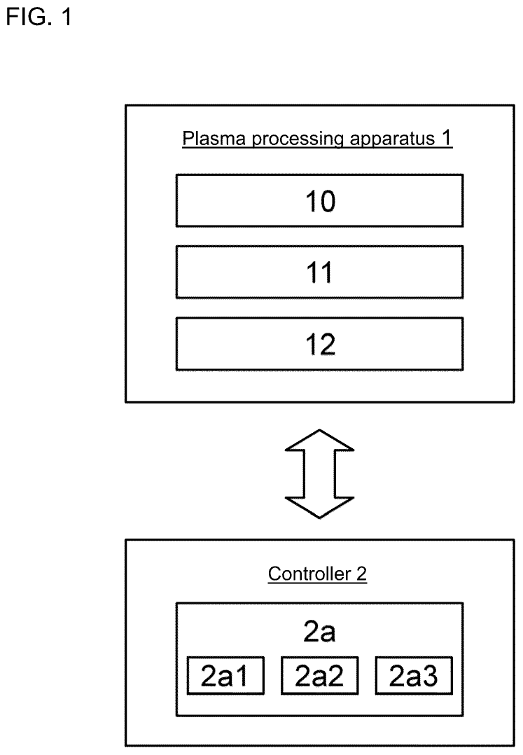

A plasma processing system according to one embodiment will be described first with reference to FIG. 1. FIG. 1 is a diagram of a plasma processing system with an example structure.

In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas inlet for receiving at least one process gas supplied into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 maycontrol the components of the plasma processing apparatus 1 to perform the various steps described herein. In one embodiment, some or all of the components of the controller 2 maybe included in the plasma processing apparatus 1. The controller 2 mayinclude a processor 2a1, a storage 2a2, and a communication interface 2a3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a, or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

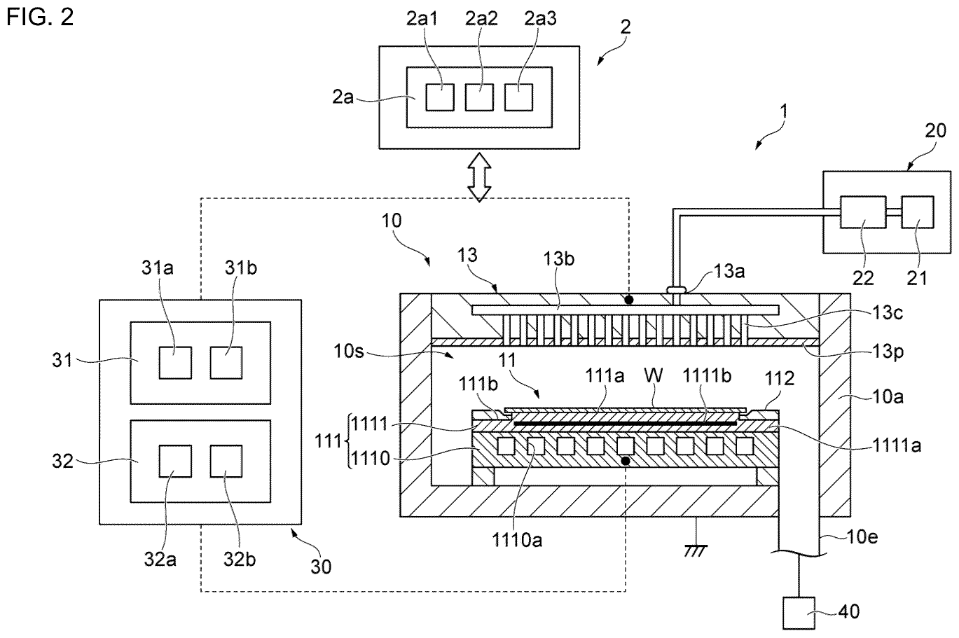

An example structure of a capacitively coupled plasma processing apparatus as an example of the plasma processing apparatus 1 will now be described. FIG. 2 is a diagram of the capacitively coupled plasma processing apparatus with an example structure.

The capacitively coupled plasma processing apparatus 1 includes the plasma processing chamber 10, the gas supply 20, a power supply 30, and the exhaust system 40. The plasma processing apparatus 1 also includes the substrate support 11 and a gas inlet unit. The gas inlet unit allows at least one process gas to be introduced into the plasma processing chamber 10. The gas inlet unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. The substrate W is, for example, a wafer. The annular portion 111b of the body 111 surrounds the central portion 111a of the body 111 as viewed in plan. The substrate W is placed on the central portion 111a of the body 111. The ring assembly 112 is placed on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

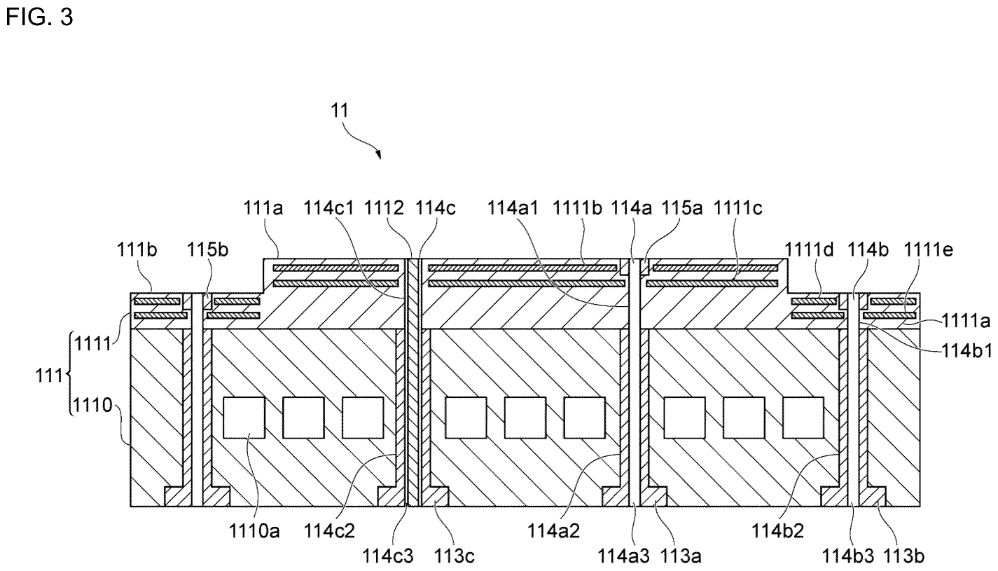

In one embodiment, the body 111 includes a base 1110 and an ESC 1111. The base 1110 includes a conductive structure. The conductive structure in the base 1110 mayserve as a lower electrode. The ESC 1111 is located on the base 1110. The ESC 1111 includes a dielectric structure 1111a and a first electrode layer 1111b. The first electrode layer 1111b is located inside the dielectric structure 1111a as an electrostatic clamp electrode (also referred to as an electrostatic electrode, a chuck electrode, or a clamping electrode). The dielectric structure 1111a includes, for example, a ceramic material. The first electrode layer 1111b has a thickness of, for example, 10 to 300 micrometers (μm). The dielectric structure 1111a includes the central portion 111a. In one embodiment, the dielectric structure 1111a also includes the annular portion 111b. The annular portion 111b may be included in a separate structure surrounding the ESC 1111, such as an annular ESC or an annular insulating structure. In this case, the ring assembly 112 may be located on the annular ESC or the annular insulating structure, or may be located on both the ESC 1111 and the annular insulating structure. A second electrode layer (described later with reference to FIG. 3) is located inside the dielectric structure 1111a. The second electrode layer serves as at least one RF electrode coupled to an RF power supply 31 (described later), at least one DC electrode coupled to a DC power supply 32 (described later), or both the RF electrode and the DC electrode. The second electrode layer has a thickness of, for example, 10 to 300 μm. In this case, the RF electrode, the DC electrode, or both the electrodes serve as lower electrodes. When at least one of a bias RF signal or a DC signal (described later) is provided to at least one RF electrode, to at least one DC electrode, or to both the electrodes, at least one of the RF electrode or the DC electrode is also referred to as a bias electrode. The conductive structure in the base 1110 and at least one RF electrode, the conductive structure and at least one DC electrode, or the conductive structure and both the electrodes may serve as multiple lower electrodes. The first electrode layer 1111b (electrostatic clamp electrode) may also serve as a lower electrode. Thus, the substrate support 11 includes at least one lower electrode.

The ring assembly 112 includes one or more annular structures. In one embodiment, one or more annular structures include one or more edge rings and at least one cover ring. The edge ring is formed from a conductive material or an insulating material. The cover ring is formed from an insulating material.

The substrate support 11 mayalso include a temperature control module that adjusts the temperature of at least one of the ESC 1111, the ring assembly 112, or the substrate to a target temperature. The temperature control module may include a heater, a heat transfer medium, a channel 1110a, or a combination of these. The channel 1110a allows a heat transfer fluid such as brine or gas to flow. In one embodiment, the channel 1110a is defined in the base 1110, and one or more heaters are located in the dielectric structure 1111a in the ESC 1111. The substrate support 11 includes a heat transfer gas supply to supply a heat transfer gas into a space between the back surface of the substrate W and the central portion 111a.

The shower head 13 introduces at least one process gas from the gas supply 20 into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas inlet unit may include one or more side gas injectors (SGIs) installed in one or more openings in the side wall 10a.

The gas supply 20 mayinclude at least one gas source 21 and at least one flow controller 22. In one embodiment, the gas supply 20 allows supply of at least one process gas from the corresponding gas source 21 to the shower head 13 through the corresponding flow controller 22. The flow controller 22 mayinclude, for example, a mass flow controller or a pressure-based flow controller. The gas supply 20 mayfurther include at least one flow rate modulator that allows supply of at least one process gas at a modulated flow rate or in a pulsed manner.

The power supply 30 includes the RF power supply 31 that is coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the plasma to the substrate W.

In one embodiment, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated source RF signal or the generated multiple source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated bias RF signal or the generated multiple bias RF signals are provided to at least one lower electrode. In various embodiments, at least one of the source RF signal or the bias RF signal may be pulsed.

The power supply 30 mayinclude the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode, to at least one upper electrode, or to both the electrodes. The voltage pulses may have a rectangular, trapezoidal, or triangular pulse waveform, or a combination of these pulse waveforms. In one embodiment, a waveform generator for generating a sequence of voltage pulses based on DC signals is located between the first DC generator 32a and at least one lower electrode. Thus, the first DC generator 32a and the waveform generator are included in a voltage pulse generator. When the second DC generator 32b and the waveform generator are included in a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 mayinclude the first DC generator 32a and the second DC generator 32b in addition to the RF power supply 31, or the first DC generator 32a may replace the second RF generator 31b.

The exhaust system 40 is connectable to, for example, a gas outlet 10e in the bottom of the plasma processing chamber 10. The exhaust system 40 mayinclude a pressure control valve and a vacuum pump. The pressure control valve regulates the pressure in the plasma processing space 10s. The vacuum pump may include a turbomolecular pump, a dry pump, or a combination of these.

### Substrate Support

The structure of the substrate support 11 will now be described with reference to FIG. 3. FIG. 3 is a schematic cross-sectional view of the substrate support 11 in one embodiment.

As described above, the body 111 in the substrate support 11 includes the base 1110 and the ESC 1111.

The base 1110 is formed from, for example, a conductive material such as aluminum. The base 1110 has the channel 1110a described above. In one embodiment, the base 1110 and the ESC 1111 are integral with each other with, for example, an adhesive layer between them. The base 1110 maybe formed from an insulating ceramic material such as SiC. In this case, the base 1110 does not serve as a lower electrode.

The ESC 1111 includes the dielectric structure 1111a as described above. The dielectric structure 1111a is substantially disk-shaped. The dielectric structure 1111a is formed from a ceramic material such as aluminum oxide or aluminum nitride. The dielectric structure 1111a includes the central portion 111a and the annular portion 111b described above. The dielectric structure 1111a may be formed from a thermally sprayed ceramic material.

In one embodiment, the central portion 111a has a smaller diameter than the substrate W and is at a higher level than the annular portion 111b. The substrate W supported on the central portion 111a thus has its periphery extending horizontally from the central portion 111a.

In the example in FIG. 3, the dielectric structure 1111a being a single structure includes the central portion 111a and the annular portion 111b. The dielectric structure 1111amay be divided into a central part and an annular part. In this case, the central part may include the central portion 111a, and the annular part may include the annular portion 111b. In the example in FIG. 3, the central part and the annular part are integral with each other. The central part and the annular part may be separate from each other.

The ESC 1111 includes the first electrode layer 1111b and a second electrode layer 1111c that are located inside the dielectric structure 1111a and below the central portion 111a. The first electrode layer 1111b receives power from an AC power supply or a DC power supply. This generates an electrostatic force to cause the substrate W to be electrostatically held on the central portion 111a. In other words, the first electrode layer 1111b serves as an electrostatic clamp electrode for the substrate W. In one embodiment, the first electrode layer 1111b is circular as viewed in plan. The first electrode layer 1111b may include, for example, multiple electrode layer segments divided in at least one of the radial direction or the circumferential direction.

The second electrode layer 1111c is located below the first electrode layer 1111b. The second electrode layer 1111c receives at least one of a bias RF signal or a DC signal from an RF power supply or a DC power supply, or in other words, a bias power supply. This causes ions in the plasma to be drawn to the substrate W on the central portion 111a. In other words, the second electrode layer 1111c serves as a bias electrode. In one embodiment, the second electrode layer 1111c is circular as viewed in plan. The second electrode layer 1111c may include, for example, multiple electrode layer segments divided in at least one of the radial direction or the circumferential direction. The bias power supply may be the second RF generator 31b or the first DC generator 32a described above.

The base 1110 has, below the central portion 111a, a through-hole 114a2 extending through the base 1110 from the lower surface to the upper surface of the base 1110. The dielectric structure 1111a has a through-hole 114a1 extending through the dielectric structure 1111a from the lower surface of the dielectric structure 1111a to the central portion 111a. The through-hole 114a1 in the dielectric structure 1111a connects with the through-hole 114a2 in the base 1110. The through-hole 114a1 in the dielectric structure 1111a and the through-hole 114a2 in the base 1110 define a heat transfer gas supply hole 114a to supply a heat transfer gas into the space between the back surface of the substrate W and the central portion 111a. The heat transfer gas supply hole 114a may be circular. In one embodiment, multiple heat transfer gas supply holes 114a are located in the central portion 111a. More specifically, the dielectric structure 1111a has multiple through-holes 114a1 extending through the dielectric structure 1111a from the lower surface to the central portion 111a, and the base 1110 has, below the central portion 111a, multiple through-holes 114a2 extending through the base 1110 from the lower surface to the upper surface of the base 1110. The through-holes 114a1 in the dielectric structure 1111a and the corresponding through-holes 114a2 in the base 1110 define the multiple heat transfer gas supply holes 114a.

The ESC 1111 further includes at least one conductive structure 115a (described later) surrounding the heat transfer gas supply hole 114a. The conductive structure 115a is at least partially located inside the ESC 1111 to surround the heat transfer gas supply hole 114a.

The base 1110 includes a sleeve 113a received in the through-hole 114a2 in the base 1110. The sleeve 113a is formed from an insulating material. The sleeve 113a is substantially cylindrical and has a through-hole 114a3. The through-hole 114a3 in the sleeve 113a connects with the through-hole 114a1 in the dielectric structure 1111a. Thus, the through-hole 114a1 in the dielectric structure 1111a and the through-hole 114a3 in the sleeve 113a define the heat transfer gas supply hole 114a. The sleeve 113a insulates the base 1110 from the heat transfer gas supply hole 114a. The sleeve 113a is fixed to the base 1110 with a bonding layer. The sleeve 113a may be removably attached to the base 1110 without a bonding layer between them. The sleeve 113a may have a dual structure including an inner sleeve and an outer sleeve. In this case, the inner sleeve may be removably attached to the outer sleeve.

The base 1110 has, below the central portion 111a, a through-hole 114c2 extending through the base 1110 from the lower surface to the upper surface of the base 1110. The dielectric structure 1111a has a through-hole 114c1 extending through the dielectric structure 1111a from the lower surface of the dielectric structure 1111a to the central portion 111a. The through-hole 114c1 in the dielectric structure 1111a connects with the through-hole 114c2 in the base 1110. The through-hole 114c1 in the dielectric structure 1111a and the through-hole 114c2 in the base 1110 define a lifter pin through-hole 114c. The lifter pin through-hole 114c receives a lifter pin 1112 that can be raised and lowered. The lifter pin through-hole 114c may be circular. The lifter pin 1112 is raised from the central portion 111a to lift the substrate W supported on the central portion 111a. In one embodiment, three lifter pins 1112 and three lifter pin through-holes 114c are located in the central portion 111a. More specifically, the dielectric structure 1111a has at least three through-holes 114c1 extending through the dielectric structure 1111a from the lower surface to the central portion 111a, and the base 1110 has at least three through-holes 114c2 extending through the base 1110 from the lower surface to the upper surface of the base 1110. At least three through-holes 114c1 in the dielectric structure 1111a and the corresponding at least three through-holes 114c2 in the base 1110 define at least three lifter pin through-holes 114c.

The base 1110 includes a sleeve 113c received in the through-hole 114c2 in the base 1110. The sleeve 113c is formed from an insulating material. The sleeve 113c is substantially cylindrical and has a through-hole 114c3. The through-hole 114c3 in the sleeve 113c connects with the through-hole 114c1 in the dielectric structure 1111a. Thus, the through-hole 114c1 in the dielectric structure 1111a and the through-hole 114c3 in the sleeve 113c define the lifter pin through-hole 114c. The sleeve 113c insulates the base 1110 from the lifter pin through-hole 114c. The sleeve 113c is fixed to the base 1110 with a bonding layer. The sleeve 113c may be removably attached to the base 1110 without a bonding layer between them. The sleeve 113c may have a dual structure including an inner sleeve and an outer sleeve. In this case, the inner sleeve may be removably attached to the outer sleeve.

The dielectric structure 1111a includes a third electrode layer 1111d and a fourth electrode layer 1111e below the annular portion 111b. The third electrode layer 1111d receives power from the AC power supply or the DC power supply. This generates an electrostatic force to cause the ring assembly 112 (edge ring) to be electrostatically held on the annular portion 111b. In other words, the third electrode layer 1111d serves as an electrostatic clamp electrode for the edge ring. In one embodiment, the third electrode layer 1111d is annular as viewed in plan. The third electrode layer 1111d may include, for example, multiple electrode layer segments divided in at least one of the radial direction or the circumferential direction. Although the third electrode layer 1111d and the fourth electrode layer 1111e are both located inside the dielectric structure 1111a in the example in FIG. 3, the structure is not limited to this example. For example, either the third electrode layer 1111d or the fourth electrode layer 1111e may be located inside the dielectric structure 1111a.

The fourth electrode layer 1111e is located below the third electrode layer 1111d. The fourth electrode layer 1111e receives at least one of a bias RF signal or a DC signal from the RF power supply or the DC power supply. This adjusts a plasma sheath in the peripheral portion of the substrate W and above the edge ring, thus improving uniformity across the plasma processing plane. In one embodiment, the fourth electrode layer 1111e is annular as viewed in plan. The fourth electrode layer 1111e may include, for example, multiple electrode layer segments divided in at least one of the radial direction or the circumferential direction.

The base 1110 has, below the annular portion 111b, a through-hole 114b2 extending through the base 1110 from the lower surface to the upper surface of the base 1110. The dielectric structure 1111a has a through-hole 114b1 extending through the dielectric structure 1111a from the lower surface of the dielectric structure 1111a to the annular portion 111b. The through-hole 114b1 in the dielectric structure 1111a connects with the through-hole 114b2 in the base 1110. The through-hole 114b1 in the dielectric structure 1111a and the through-hole 114b2 in the base 1110 define a heat transfer gas supply hole 114b to supply a heat transfer gas into a space between the back surface of the edge ring and the annular portion 111b. The heat transfer gas supply hole 114b is substantially cylindrical. In one embodiment, multiple heat transfer gas supply holes 114b are located in the annular portion 111b. More specifically, the dielectric structure 1111a has multiple through-holes 114b1 extending through the dielectric structure 1111a from the lower surface to the annular portion 111b. The base 1110 has, below the annular portion 111b, multiple through-holes 114b2 extending through the base 1110 from the lower surface to the upper surface of the base 1110. The through-holes 114b1 in the dielectric structure 1111a and the corresponding through-holes 114b2 in the base 1110 define multiple heat transfer gas supply holes 114b.

The ESC 1111 further includes a conductive structure 115b (described later) surrounding the heat transfer gas supply hole 114b. At least a part of the conductive structure 115b is located inside the ESC 1111 to surround the heat transfer gas supply hole 114b.

The base 1110 includes a sleeve 113b received in the through-hole 114b2 in the base 1110. The sleeve 113b is formed from an insulating material. The sleeve 113b is substantially cylindrical and has a through-hole 114b3. The through-hole 114b3 in the sleeve 113b connects with the through-hole 114b1 in the dielectric structure 1111a. Thus, the through-hole 114b1 in the dielectric structure 1111a and the through-hole 114b3 in the sleeve 113b define the heat transfer gas supply hole 114b. The sleeve 113b insulates the base 1110 from the heat transfer gas supply hole 114b. The sleeve 113b is fixed to the base 1110 with a bonding layer. The sleeve 113b may be removably attached to the base 1110 without a bonding layer between them. The sleeve 113b may have a dual structure including an inner sleeve and an outer sleeve. In this case, the inner sleeve may be removably attached to the outer sleeve.

In one embodiment, the structure may include a lifter pin that can lift the edge ring supported on the annular portion 111b. In this case, the lifter pin is received in a lifter pin through-hole with the same structure as the lifter pin through-hole 114c.

In one or more embodiments of the disclosure, the conductive structure 115a surrounds the heat transfer gas supply hole 114a and extends upward from the same level as the second electrode layer 1111c in the height direction or from a higher level than the second electrode layer 1111c. This reduces the likelihood that the potential difference in the heat transfer gas supply hole 114a exceeds the breakdown voltage defined by Paschen's Law, thus preventing or reducing occurrence of abnormal discharge in the heat transfer gas supply hole 114a. Similarly, the conductive structure 115b surrounds the heat transfer gas supply hole 114b and extends upward from the same level as the fourth electrode layer 1111e in the height direction or from a higher level than the fourth electrode layer 1111e. This prevents or reduces occurrence of abnormal discharge in the heat transfer gas supply hole 114b.

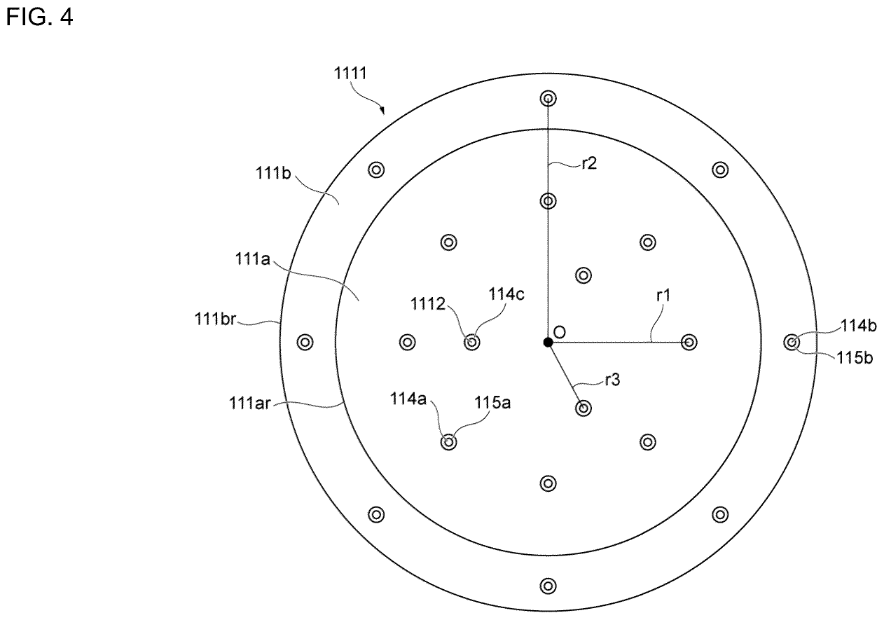

The structure of the ESC 1111 as viewed from above will now be described with reference to FIG. 4.

In FIG. 4, the central portion 111a is substantially circular and has an outer edge 111ar. The annular portion 111b is annular and defined by the outer edge 111ar of the central portion 111a and an outer edge 111br of the annular portion 111b. The annular portion 111b is concentric with the central portion 111a.

In the example in FIG. 4, in the central portion 111a, eight heat transfer gas supply holes 114a are arranged at equal distances r1 from a center O of the ESC 1111 and at equal intervals in the circumferential direction of the central portion 111a. Although the heat transfer gas supply holes 114a are arranged at equal intervals in the circumferential direction of the central portion 111a in the example in FIG. 4, the structure is not limited to this example. The central portion 111 may have at least one heat transfer gas supply hole 114a, or the heat transfer gas supply holes 114a may be arranged at unequal intervals in the circumferential direction of the central portion 111a.

In the example in FIG. 4, in the annular portion 111b, eight heat transfer gas supply holes 114b are arranged at equal distances r2 from the center O of the ESC 1111 and at equal intervals in the circumferential direction of the annular portion 111b. Although the heat transfer gas supply holes 114b are arranged at equal intervals in the circumferential direction of the annular portion 111b in the example in FIG. 4, the structure is not limited to this example. The annular portion 111b may have at least one heat transfer gas supply hole 114b, or the heat transfer gas supply holes 114b may be arranged at unequal intervals in the circumferential direction of the annular portion 111b.

In the example in FIG. 4, three lifter pin through-holes 114c are arranged at equal distances r3 from the center O of the ESC 1111 in the central portion 111a. Although the structure in the example in FIG. 4 has the three lifter pin through-holes 114c, the number of lifter pin through-holes 114c is not limited to this example. The structure may have four or more lifter pin through-holes 114c.

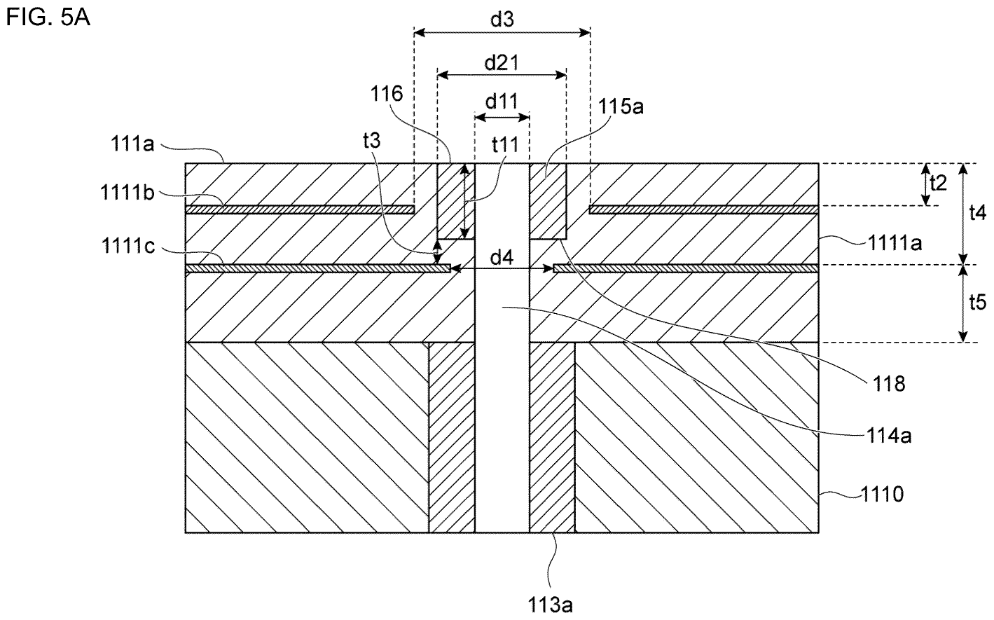

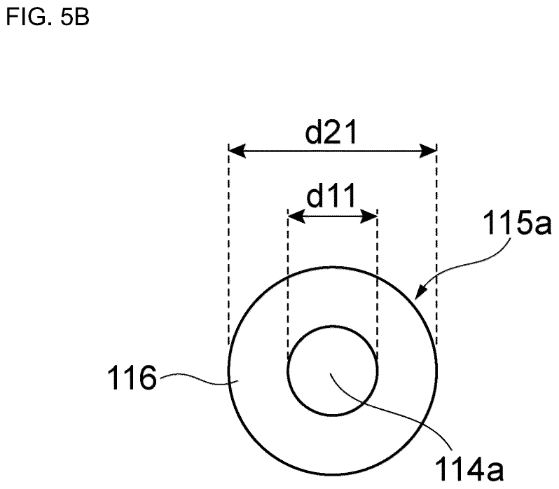

The arrangement of the conductive structure 115a will now be described with reference to FIGS. 5A to 13B.

### First Embodiment

FIG. 5A is a sectional view of a conductive structure 115a in a first embodiment. FIG. 5B is a top view of the conductive structure 115a in the first embodiment. In the present embodiment, the conductive structure 115a is substantially cylindrical as a single structure and located inside the dielectric structure 1111a to surround the heat transfer gas supply hole 114a. The conductive structure 115a is formed from a conductive ceramic material. The conductive ceramic material is prepared by, for example, mixing aluminum oxide (Al₂O₃) with a metal carbide and firing the mixture. The metal carbide is, for example, tungsten carbide (WC). The material for the conductive structure 115a is not limited a conductive ceramic material and may be a metal.

In the example in FIG. 5A, the conductive structure 115a has an inner diameter d11. In the example in FIG. 5A, the conductive structure 115a is exposed to the heat transfer gas supply hole 114a. In other words, the conductive structure 115a defines a part of the heat transfer gas supply hole 114a. The conductive structure 115a thus has the inner diameter d11 substantially equal to the diameter of the heat transfer gas supply hole 114a. The conductive structure 115a has an outer diameter d21. The conductive structure 115a has the outer diameter d21 smaller than a diameter d3 of an opening in the first electrode layer 1111b. In the example in FIG. 5A, the conductive structure 115a has the outer diameter d21 larger than a diameter d4 of an opening in the second electrode layer 1111c. The conductive structure 115a may have the outer diameter d21 smaller than the diameter d4 of the opening in the second electrode layer 1111c.

In the example in FIG. 5A, the inner diameter d11 is, for example, 0.1 to 1 millimeters (mm). The outer diameter d21 is, for example, 1 to 5 mm. The diameter d3 of the opening in the first electrode layer 1111b is, for example, 1.5 to 9 mm. The diameter d4 of the second electrode layer 1111c is, for example, 0.6 to 9 mm.

In the example in FIG. 5B, the conductive structure 115a has an annular shape with the inner diameter d11 and the outer diameter d21 as viewed from above.

In the example in FIG. 5A, the second electrode layer 1111c is below the central portion 111a by a distance t4, and is above the upper surface of the base 1110 by a distance t5. In the example in FIG. 5A, the conductive structure 115a extends upward from a higher level than the second electrode layer 1111c. The conductive structure 115a has a lower surface 118 located above the second electrode layer 1111c by a distance t3. The conductive structure 115a may have the lower surface 118 at the same level as the second electrode layer 1111c in the height direction. In the example in FIG. 5A, the conductive structure 115a has an upper surface 116 substantially flush with the central portion 111a. The conductive structure 115a may have the upper surface 116 below the central portion 111a. The conductive structure 115a may have the upper surface 116 above the central portion 111a. In the latter case, the conductive structure 115a may have the upper surface 116 to come in contact with the substrate W supported on the substrate support 11.

In the example in FIG. 5A, the conductive structure 115a has a thickness t11 in the vertical direction. The thickness t11 is smaller than the distance t4. The thickness t11 is larger than an interval t2 between the central portion 111a and the first electrode layer 1111b. The thickness t11 may be equal to the interval t2, or may be smaller than the interval t2.

In the example in FIG. 5A, the thickness t11 is, for example, 0.25 to 2.5 mm. The interval t2 is, for example, 0.25 to 1 mm. The distance t3 is, for example, 0.25 to 2.5 mm. The distance t4 is, for example, 0.25 to 2.5 mm. The distance t5 is, for example, 0.25 to 5 mm.

The conductive structure 115a in the present embodiment reduces the likelihood that the potential difference in the heat transfer gas supply hole 114a exceeds the breakdown voltage defined by Paschen's Law, thus preventing or reducing occurrence of abnormal discharge in the heat transfer gas supply hole 114a. In the present embodiment, the conductive structure 115a can have a smaller inner diameter d11 in the heat transfer gas supply hole 114a to have intended conductance to the heat transfer gas. This also prevents or reduces the temperature difference across the substrate W during plasma processing.

Although the single conductive structure 115a surrounds the through-hole in the example in FIGS. 5A and 5B, the structure is not limited to this example. For example, multiple conductive structures 115a may surround the through-hole.

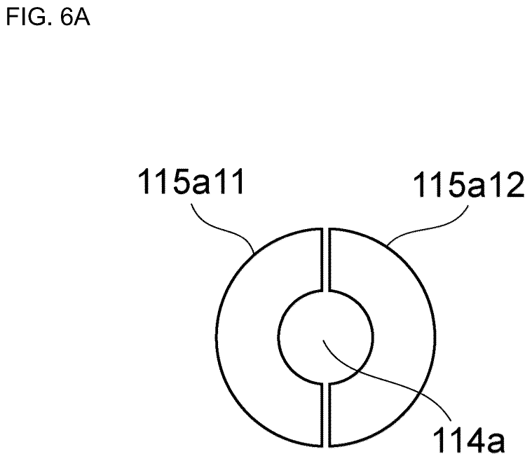

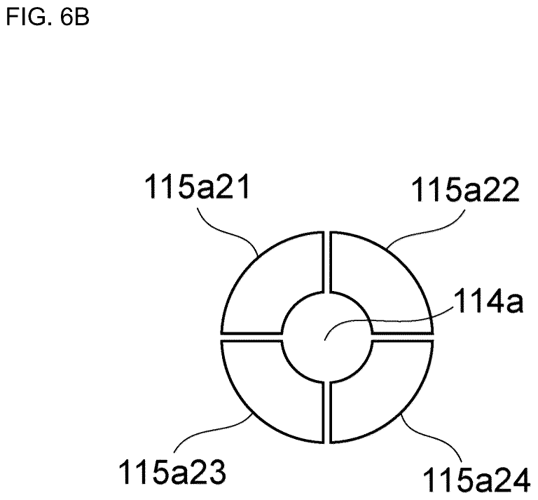

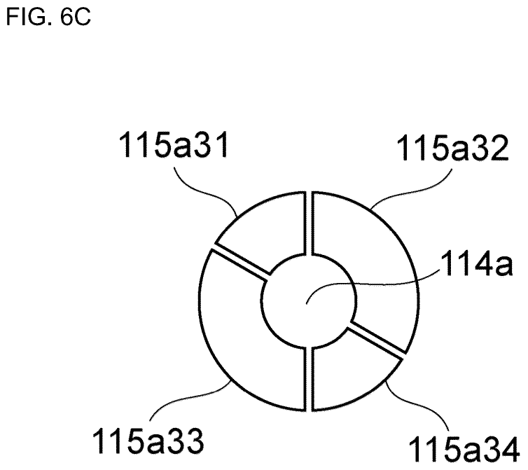

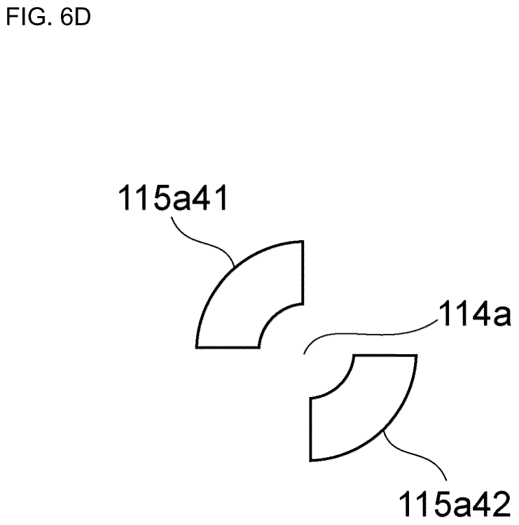

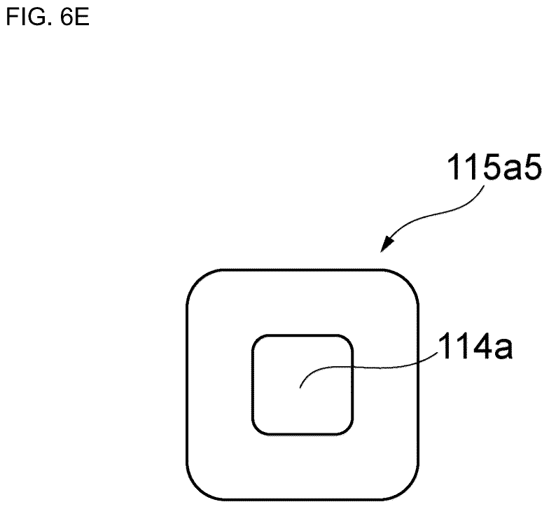

FIGS. 6A to 6E are each a diagram of conductive structures 115a in a modification of the first embodiment. In the example shown in FIG. 6A, a conductive structure 115a11 and a conductive structure 115a12 surround the heat transfer gas supply hole 114a. The conductive structure 115a11 and the conductive structure 115a12 have substantially the same shape and are symmetric to each other about the heat transfer gas supply hole 114a to surround the heat transfer gas supply hole 114a. In the example shown in FIG. 6B, a conductive structure 115a21, a conductive structure 115a22, a conductive structure 115a23, and a conductive structure 115a24 surround the heat transfer gas supply hole 114a. The conductive structure 115a21, the conductive structure 115a22, the conductive structure 115a23, and the conductive structure 115a24 have substantially the same shape and are arranged circumferentially at equal intervals about the heat transfer gas supply hole 114a to surround the heat transfer gas supply hole 114a. In the example shown in FIG. 6C, a conductive structure 115a31, a conductive structure 115a32, a conductive structure 115a33, and a conductive structure 115a34 surround the heat transfer gas supply hole 114a. The conductive structure 115a31 and the conductive structure 115a34 have substantially the same shape and are symmetric to each other about the heat transfer gas supply hole 114a to surround the heat transfer gas supply hole 114a. The conductive structure 115a32 and the conductive structure 115a33 have substantially the same shape and are symmetric to each other about the heat transfer gas supply hole 114a to surround the heat transfer gas supply hole 114a. The conductive structure 115a31 and the conductive structure 115a34 each have a shape different from the shape of each of the conductive structure 115a32 and the conductive structure 115a33. In the example shown in FIG. 6D, a conductive structure 115a41 and a conductive structure 115a42 surround the heat transfer gas supply hole 114a. The conductive structure 115a41 and the conductive structure 115a42 have substantially the same shape and are symmetric to each other about the heat transfer gas supply hole 114a. The conductive structure 115a41 and the conductive structure 115a42 in the example shown in FIG. 6D surround a smaller portion of the heat transfer gas supply hole 114a than in the example shown in FIG. 6A. The conductive structure 115a41 and the conductive structure 115a42 may have different shapes.

Although the conductive structure 115a is substantially cylindrical in the example in FIGS. 5A and 5B, the conductive structure 115a may have any other shape. For example, as shown in FIG. 6E, a conductive structure 115a5 may have a rectangular shape, or may have any other polygonal shape. In this case, the conductive structure 115a5 may have an inner periphery partially exposed to the heat transfer gas supply hole 114a.

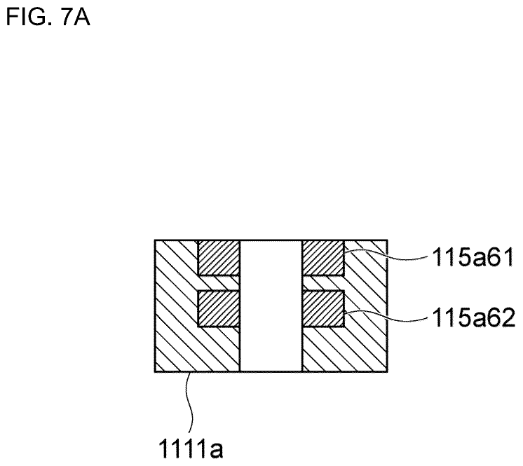

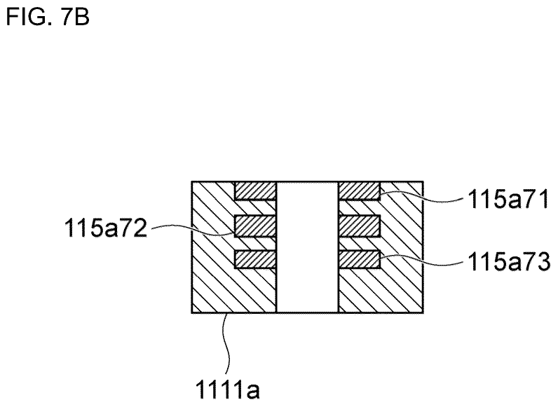

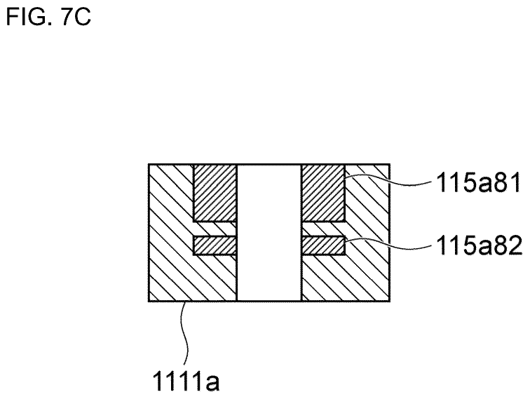

Although multiple conductive structures 115a are arranged in the circumferential direction in the examples in FIGS. 6A to 6D, the structure is not limited to these examples. For example, multiple conductive structures may be arranged in the vertical direction to surround the through-hole. FIGS. 7A to 7C are each a diagram of conductive structures 115a in a modification of the first embodiment. In the example shown in FIG. 7A, a conductive structure 115a61 and a conductive structure 115a62 surround the heat transfer gas supply hole 114a. The conductive structure 115a61 and the conductive structure 115a62 have substantially the same thickness and are spaced from each other in the vertical direction to surround the heat transfer gas supply hole 114a. In the example shown in FIG. 7B, a conductive structure 115a71, a conductive structure 115a72, and a conductive structure 115a73 each surround the heat transfer gas supply hole 114a. The conductive structure 115a71, the conductive structure 115a72, and the conductive structure 115a73 have substantially the same thickness and are arranged at equal intervals in the vertical direction to surround the heat transfer gas supply hole 114a. The conductive structure 115a71, the conductive structure 115a72, and the conductive structure 115a73 may have different thicknesses or may be arranged at unequal intervals. In the example shown in FIG. 7C, a conductive structure 115a81 and a conductive structure 115a82 surround the heat transfer gas supply hole 114a. The conductive structure 115a81 and the conductive structure 115a82 have different thicknesses and are spaced from each other in the vertical direction to surround the heat transfer gas supply hole 114a.

The examples in FIGS. 6A to 6E and the examples in FIGS. 7A to 7C described above may be combined as appropriate.

### Second Embodiment

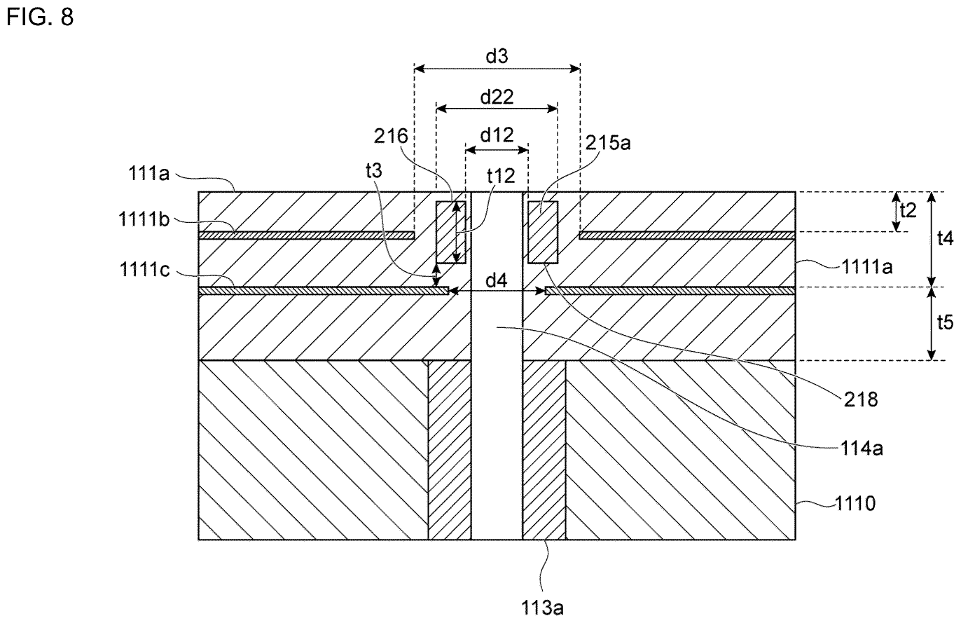

FIG. 8 is a sectional view of a conductive structure 215a in a second embodiment. the example in FIG. 8, the conductive structure 215a is fully embedded in the dielectric structure 1111a. More specifically, the conductive structure 215a has an upper surface 216 below the central portion 111a and has an inner diameter d12 larger than the diameter of the heat transfer gas supply hole 114a. In the example in FIG. 8, the conductive structure 215a extends upward from a higher level than the second electrode layer 1111c. The conductive structure 215a has a lower surface 218 located above the second electrode layer 1111c by a distance t3. The conductive structure 215a may have the lower surface 218 at the same level as the second electrode layer 1111c.

The conductive structure 215a has an outer diameter d22 smaller than the diameter d3 of the opening in the first electrode layer 1111b. In the example in FIG. 8, the conductive structure 215a has the outer diameter d22 larger than the diameter d4 of the opening in the second electrode layer 1111c. The conductive structure 215a may have the outer diameter d22 smaller than the diameter d4 of the opening in the second electrode layer 1111c.

In the present embodiment, the conductive structure 215a has a thickness t12 in the vertical direction. The thickness t12 is smaller than the distance t4. In the example in FIG. 8, the thickness t12 is larger than the interval t2 between the central portion 111a and the first electrode layer 1111b. The thickness t12 may be smaller than the interval t2.

In the example in FIG. 8, the inner diameter d12 is, for example, 0.1 to 1 mm. The outer diameter d22 is, for example, 1 to 5 mm.

In the present embodiment, the conductive structure 215a is fully embedded in the dielectric structure 1111a, and thus is not exposed to the plasma during plasma processing. This prevents the plasma processing space 10s from being contaminated with the material of the conductive structure 215a.

### Third Embodiment

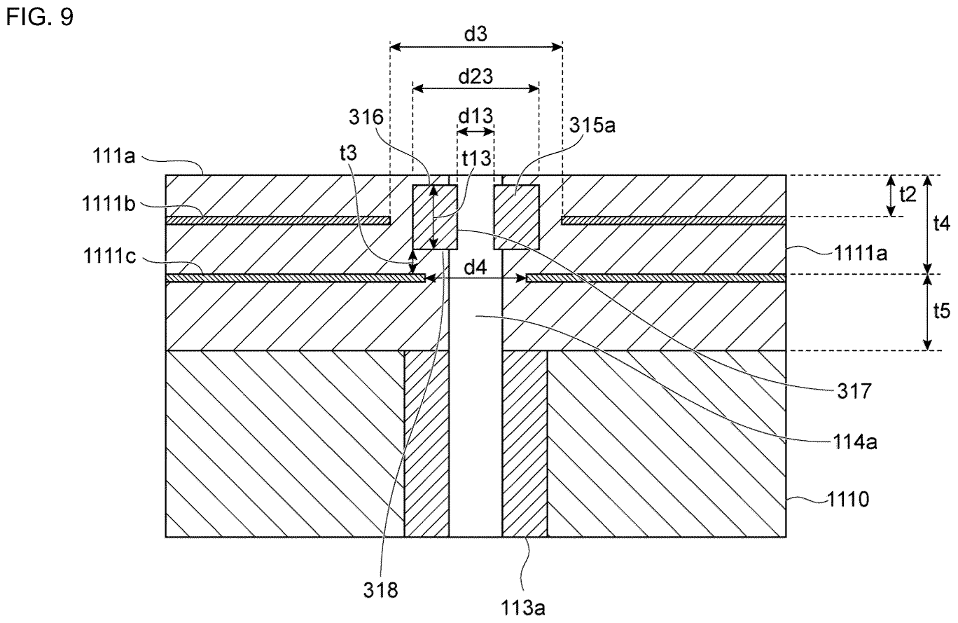

FIG. 9 is a sectional view of a conductive structure 315a in a third embodiment. In the example in FIG. 9, the conductive structure 315a has an inner circumferential surface 317 exposed to the heat transfer gas supply hole 114a. The conductive structure 315a has an inner diameter d13 smaller than or equal to the diameter of the heat transfer gas supply hole 114a. In the example in FIG. 9, the conductive structure 315a extends upward from a higher level than the second electrode layer 1111c. The conductive structure 315a has a lower surface 318 located above the second electrode layer 1111c by a distance t3. The conductive structure 315a may have the lower surface 318 at the same level as the second electrode layer 1111c.

The conductive structure 315a has an outer diameter d23 smaller than the diameter d3 of the opening in the first electrode layer 1111b. In the example in FIG. 9, the conductive structure 315a has the outer diameter d23 larger than the diameter d4 of the opening in the second electrode layer 1111c. The conductive structure 315a may have the outer diameter d23 smaller than the diameter d4 of the opening in the second electrode layer 1111c.

In the present embodiment, the conductive structure 315a has a thickness t13 in the vertical direction. The thickness t13 is smaller than the distance t4. In the example in FIG. 9, the thickness t13 is larger than the interval t2 between the central portion 111a and the first electrode layer 1111b. The thickness t13 may be smaller than the interval t2. In the example in FIG. 9, the conductive structure 315a has an upper surface 316 below the central portion 111a. The conductive structure 315a may have the upper surface 316 above the central portion 111a. In this case, the conductive structure 315a may have the upper surface 316 to come in contact with the substrate W supported on the substrate support 11.

In the example in FIG. 9, the inner diameter d13 is, for example, 0.1 to 1 mm. The outer diameter d23 is, for example, 1 to 5 mm.

In the present embodiment, the inner diameter d13 of the conductive structure 315a can be smaller than the inner diameter of the heat transfer gas supply hole 114a. This reduces the volume of space in which electrons accelerate in the heat transfer gas supply hole 114a. This further reduces abnormal discharge.

### Fourth Embodiment

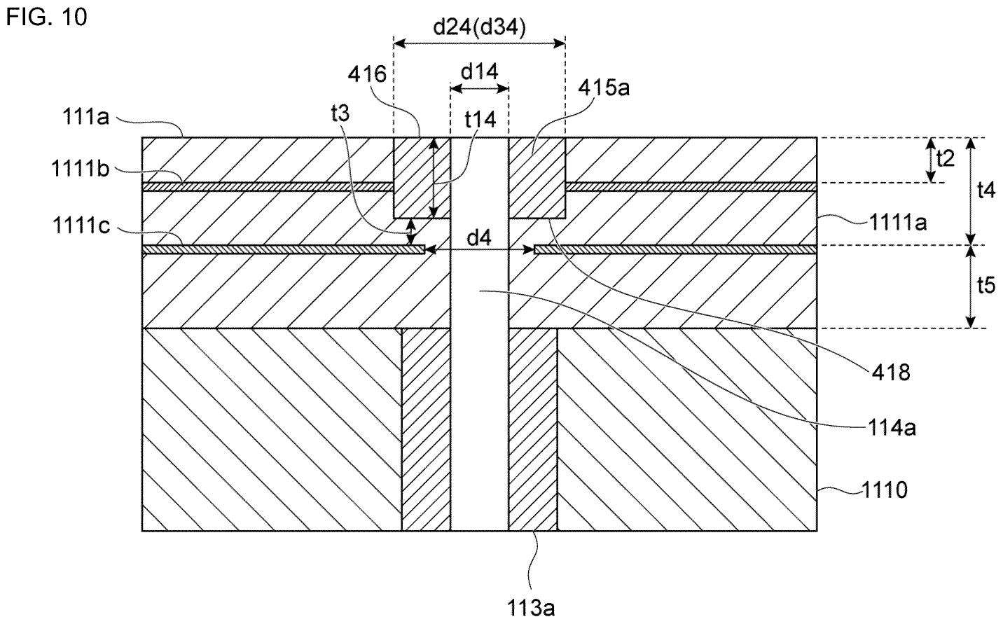

FIG. 10 is a sectional view of a conductive structure 415a in a fourth embodiment. In the example in FIG. 10, the conductive structure 415a is electrically and physically in contact with a first electrode layer 1111b. In other words, the conductive structure 415a has an outer diameter d24 substantially equal to a diameter d34 of an opening in the first electrode layer 1111b. In the example in FIG. 10, the conductive structure 415a has an inner diameter d14 substantially equal to the diameter of the heat transfer gas supply hole 114a. The conductive structure 415a may have the inner diameter d14 larger than the diameter of the heat transfer gas supply hole 114a.

In the present embodiment, the conductive structure 415a has a thickness t14 in the vertical direction. The thickness t14 is smaller than the distance t4. In the example in FIG. 10, the thickness t14 is larger than the interval t2 between the central portion 111a and the first electrode layer 1111b. The thickness t14 may be smaller than the interval t2. In the example in FIG. 10, the conductive structure 415a has an upper surface 416 substantially flush with the central portion 111a. In other words, the conductive structure 415a has the upper surface 416 serving as a part of the central portion 111a. The conductive structure 415a may have the upper surface 416 below the central portion 111a.

In the example in FIG. 10, the inner diameter d14 is, for example, 0.1 to 1 mm. The outer diameter d24 is, for example, 1 to 5 mm.

In the present embodiment, the conductive structure 415a is electrically and physically in contact with the first electrode layer 1111b. Thus, the potential of the conductive structure 415a stably remains the same as the potential of the first electrode layer 1111b without floating.

### Fifth Embodiment

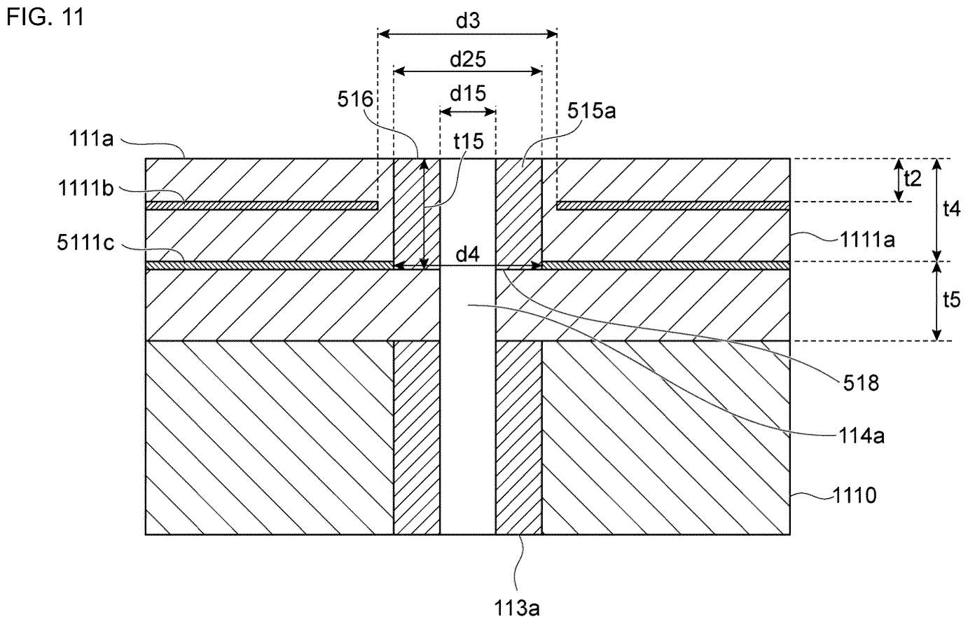

FIG. 11 is a sectional view of a conductive structure 515a in a fifth embodiment. In the example in FIG. 11, the conductive structure 515a is electrically and physically in contact with a second electrode layer 5111c. In other words, the conductive structure 515a has a lower surface 518 at substantially the same level as the second electrode layer 5111c in the height direction. The conductive structure 515a has an outer diameter d25 substantially the same as a diameter d4 of an opening in the second electrode layer 5111c. The conductive structure 515a has the outer diameter d25 smaller than the diameter d3 of the opening in the first electrode layer 1111b.

In the example in FIG. 11, the conductive structure 515a has an inner diameter d15 substantially equal to the diameter of the heat transfer gas supply hole 114a. The conductive structure 515a may have the inner diameter d15 larger than the diameter of the heat transfer gas supply hole 114a. In the example in FIG. 11, the conductive structure 515a has an upper surface 516 substantially flush with the central portion 111a. The conductive structure 515a may have the upper surface 516 below the central portion 111a.

In the example in FIG. 11, the inner diameter d15 is, for example, 0.1 to 1 mm. The outer diameter d25 is, for example, 1 to 5 mm.

In the present embodiment, the conductive structure 515a is electrically and physically in contact with the second electrode layer 5111c. Thus, the potential of the conductive structure 515a stably remains the same as the potential of the second electrode layer 5111c without floating.

### Sixth Embodiment

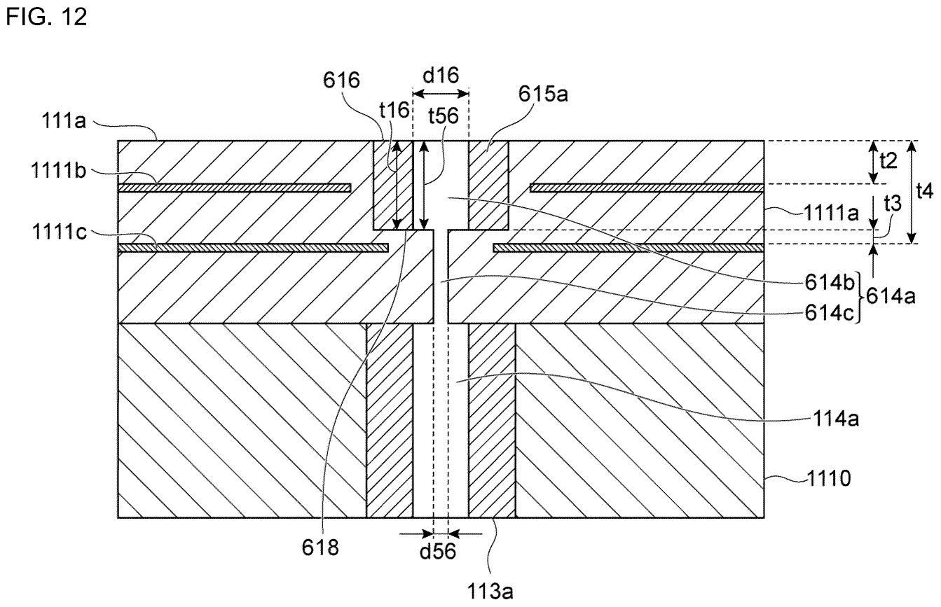

FIG. 12 is a sectional view of a conductive structure 615a and a heat transfer gas supply hole 114a in a sixth embodiment. In the present embodiment, the heat transfer gas supply hole 114a has a through-hole 614a in a dielectric structure 1111a. The through-hole 614a includes an upper portion 614b (first portion) and a lower portion 614c (second portion). The upper portion 614b is at least partially defined by an inner diameter d16 (first diameter) of the conductive structure 615a. The lower portion 614c connects with a lower portion of the upper portion 614b and is defined by an inner diameter d56 (second diameter) of the dielectric structure 1111a smaller than the inner diameter d16 of the conductive structure 615a.

In the example in FIG. 12, the upper portion 614b has a depth t56 substantially equal to a thickness t16 of the conductive structure 615a in the vertical direction and smaller than the distance t4. The upper portion 614b may have the depth t56 larger than the thickness t16.

In the present embodiment, the lower portion 614c has the inner diameter d56 smaller than the inner diameter d16 of the upper portion 614b, thus reducing the volume of space in the lower portion 614c in which electrons accelerate. This further reduces abnormal discharge.

In the example in FIG. 12, the inner diameter d16 is, for example, 1 to 5 mm. The inner diameter d56 is, for example, 0.1 to 2 mm.

### Seventh Embodiment

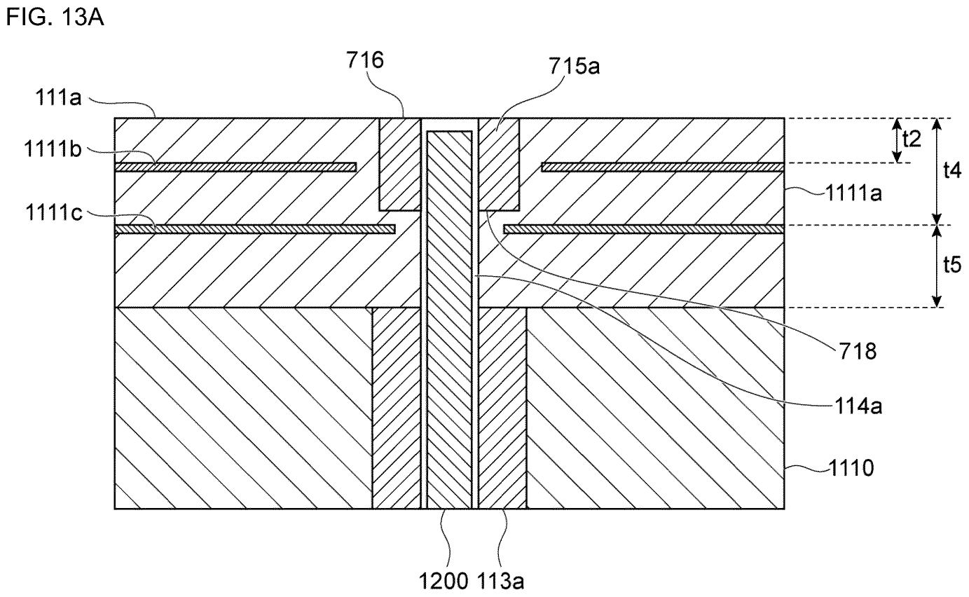

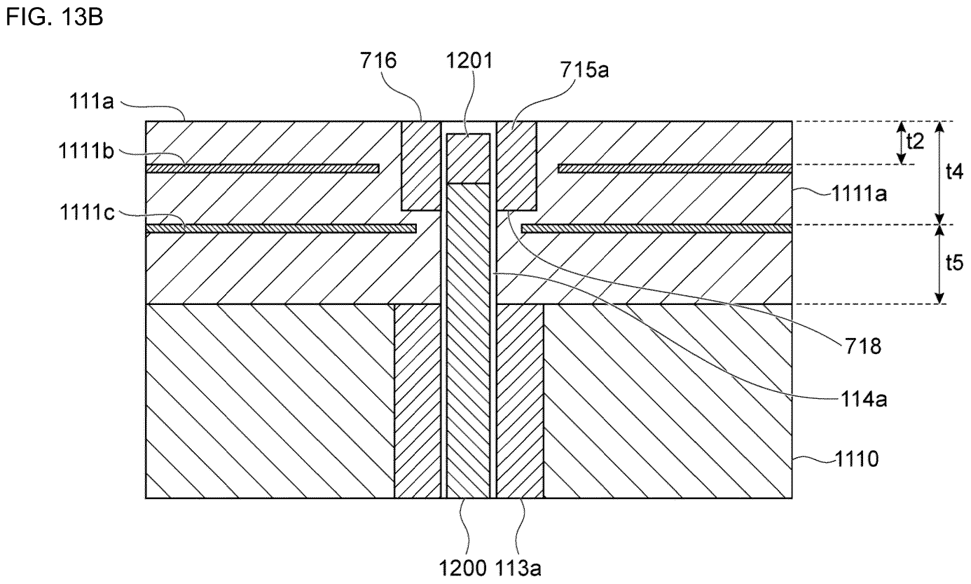

FIGS. 13A and 13B are each a sectional view of a conductive structure 715a in a seventh embodiment. In the example in FIG. 13A, a rod 1200 is received in the heat transfer gas supply hole 114a. The rod 1200 is substantially cylindrical. The rod 1200 is formed from a material with plasma resistance such as a ceramic material. The rod 1200 may extend, in the dielectric structure 1111a, from the lower surface of the dielectric structure 1111a to a position adjacent to the substrate support surface.

The rod 1200 has an outer diameter smaller than the diameter of the heat transfer gas supply hole 114a. This defines a space between the rod 1200 and the inner wall of the heat transfer gas supply hole 114a. This space serves as a channel for a heat transfer gas.

In the present embodiment, the rod 1200 is received in the heat transfer gas supply hole 114a, thus reducing the volume of space in which electrons accelerate in the heat transfer gas supply hole 114a. The effects produced by the rod 1200, in addition to the effects of the conductive structure 715a, reduce abnormal discharge further.

As in FIG. 13B, a conductive structure 1201 maybe located on a distal end of the rod 1200. In the example in FIG. 13B, the conductive structure 1201 extends upward from a higher level than the second electrode layer 1111c. The conductive structure 1201 mayextend upward from a lower level than the second electrode layer 1111c. The conductive structure 1201 maybe located across the surface of the distal end of the rod 1200 or on a part of the surface.

The structures in the above embodiments (conductive structures associated with the heat transfer gas supply hole 114a) are also applicable to the conductive structure 115b surrounding the heat transfer gas supply hole 114b. Similarly to the rod in the heat transfer gas supply hole 114a, a rod may be received in the heat transfer gas supply hole 114b as well. Either the conductive structure 115a or the conductive structure 115b may be used.

The structures in the above embodiments (conductive structures associated with the heat transfer gas supply hole 114a) are also applicable to a conductive structure surrounding the lifter pin through-hole 114c.

Although the first electrode layer 1111b and the third electrode layer 1111d serve as electrostatic clamp electrodes and the second electrode layer 1111c and the fourth electrode layer 1111e serve as bias electrodes in the embodiments of the disclosure, the structure is not limited to this. For example, one of the first electrode layer 1111b, the second electrode layer 1111c, the third electrode layer 1111d, or the fourth electrode layer 1111e may serve as a heater electrode.

Although the exemplary embodiments have been described above, the embodiments are not restrictive, and various additions, omissions, substitutions, and changes may be made. The components in the different embodiments may be combined to form another embodiment.

The present disclosure is not limited to only the above-described embodiments, which are merely exemplary. It will be appreciated by those skilled in the art that the disclosed systems and/or methods can be embodied in other specific forms without departing from the spirit of the disclosure or essential characteristics thereof. The presently disclosed embodiments are therefore considered to be illustrative and not restrictive. The disclosure is not exhaustive and should not be interpreted as limiting the claimed invention to the specific disclosed embodiments. In view of the present disclosure, one of skill in the art will understand that modifications and variations are possible in light of the above teachings or may be acquired from practicing of the disclosure.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

### REFERENCE SIGNS LIST

W Substrate
1 Plasma processing apparatus
10 Plasma processing chamber
20 Gas supply
30 Power supply
40 Exhaust system
11 Substrate support
111 Body
111a Central portion
111b Annular portion
112 Ring assembly
1110 Base
1111 Electrostatic chuck (ESC)
1111a Dielectric structure
1111b First electrode layer
1111c Second electrode layer
1111d Third electrode layer
1111e Fourth electrode layer
1112 Lifter pin
115a Conductive structure
115b Conductive structure
1200 Rod
1201 Conductive structure

1. A plasma processing apparatus, comprising:
a plasma processing chamber;
a base in the plasma processing chamber; and
an electrostatic chuck on the base,
wherein the electrostatic chuck includes
a dielectric structure having a substrate support surface and a ring support surface,
an electrostatic clamp electrode inside the dielectric structure, a bias electrode inside the dielectric structure and below the electrostatic clamp
electrode, and
at least one conductive structure at least partially located inside the dielectric structure,
the dielectric structure has a through-hole extending through the dielectric structure from the substrate support surface or the ring support surface to a lower surface of the dielectric structure, and
the at least one conductive structure surrounds the through-hole and extends upward from a same level as the bias electrode in a height direction or from a higher level than the bias electrode.

2. The plasma processing apparatus according to claim 1, wherein
the at least one conductive structure is exposed to the through-hole.

3. The plasma processing apparatus according to claim 1, wherein
the at least one conductive structure is fully embedded in the dielectric structure.

4. The plasma processing apparatus according to claim 1, wherein
the at least one conductive structure is electrically coupled to the electrostatic clamp electrode or the bias electrode.

5. The plasma processing apparatus according to claim 1, wherein
the at least one conductive structure includes a plurality of conductive structures.

6. The plasma processing apparatus according to claim 5, wherein
the plurality of conductive structures surround the through-hole in a circumferential direction.

7. The plasma processing apparatus according to claim 5, wherein
the plurality of conductive structures are arranged in a vertical direction and surround the through-hole.

8. The plasma processing apparatus according to claim 1, wherein
the at least one conductive structure comes in contact with a substrate supported on the substrate support surface or comes in contact with an edge ring supported on the ring support surface.

9. The plasma processing apparatus according to claim 1, wherein
the through-hole includes
a first portion having a first diameter, and
a second portion having a second diameter smaller than the first diameter and located below the first portion, and
the at least one conductive structure surrounds the first portion or is exposed to the first portion.

10. The plasma processing apparatus according to claim 1, further comprising:
a rod in the through-hole, the rod extending from the lower surface of the dielectric structure to a position adjacent to the substrate support surface or the ring support surface.

11. The plasma processing apparatus according to claim 10, wherein
the rod includes a conductive structure on a distal end of the rod.

12. A plasma processing apparatus, comprising:
a plasma processing chamber;
a substrate support in the plasma processing chamber; and
at least one bias power supply electrically coupled to the substrate support,
wherein the substrate support includes
a base, and
an electrostatic chuck on the base,
the electrostatic chuck includes
a dielectric structure having a substrate support surface and a ring support surface,
a first electrode layer inside the dielectric structure,
a second electrode layer inside the dielectric structure and below the first electrode layer, and
at least one conductive structure at least partially located inside the dielectric structure,
the dielectric structure has a through-hole extending through the dielectric structure from the substrate support surface or the ring support surface to a lower surface of the dielectric structure, and
the at least one conductive structure surrounds the through-hole and extends upward from a same level as the second electrode layer in a height direction or from a higher level than the second electrode layer.

13. An electrostatic chuck, comprising:
a dielectric structure having a substrate support surface and a ring support surface;
a first electrode layer inside the dielectric structure;
a second electrode layer inside the dielectric structure and below the first electrode layer, the second electrode layer being electrically coupled to a radio-frequency power supply or a direct current power supply; and
at least one conductive structure at least partially located inside the dielectric structure,
wherein the dielectric structure has a through-hole extending through the dielectric structure from the substrate support surface or the ring support surface to a lower surface of the dielectric structure, and
the at least one conductive structure surrounds the through-hole and extends upward from a same level as the second electrode layer in a height direction or from a higher level than the second electrode layer.

14. The electrostatic chuck according to claim 13, wherein
the at least one conductive structure is exposed to the through-hole.

15. The electrostatic chuck according to claim 13, wherein
the at least one conductive structure is fully embedded in the dielectric structure.

16. The electrostatic chuck according to claim 13, wherein
the at least one conductive structure is electrically coupled to the first electrode layer or the second electrode layer.

17. The electrostatic chuck according to claim 13, wherein
the at least one conductive structure includes a plurality of conductive structures.

18. The electrostatic chuck according to claim 17, wherein
the plurality of conductive structures surround the through-hole in a circumferential direction.

19. The electrostatic chuck according to claim 17, wherein
the plurality of conductive structures are arranged in a vertical direction and surround the through-hole.

20. The electrostatic chuck according to claim 13, wherein the at least one conductive structure comes in contact with a substrate supported on the substrate support surface or comes in contact with an edge ring supported on the ring support surface.

21. The electrostatic chuck according to claim 13, wherein the through-hole includes a first portion having a first diameter, and a second portion having a second diameter smaller than the first diameter and located below the first portion, and the at least one conductive structure surrounds the first portion or is exposed to the first portion.

22. The electrostatic chuck according to claim 13, further comprising:
a rod in the through-hole, the rod extending from the lower surface of the dielectric structure to a position adjacent to the substrate support surface or the ring support surface.

23. The electrostatic chuck according to claim 22, wherein the rod includes a conductive structure on a distal end of the rod.

24. The electrostatic chuck according to claim 13, wherein the first electrode layer is operable as an electrostatic clamp electrode, and the second electrode layer is operable as a bias electrode.
